(19) United States
(12) Patent Application Publication
(10) Pub. No.: US 2010/0045309 A1
(43) Pub. Date: Feb. 25, 2010

(54) METHOD AND APPARATUS FOR MEASURING FLUID PROPERTIES, INCLUDING PH

(75) Inventors: Han Zou, Windsor, NJ (US); Lucian Remus Albu, Forest Hills, NY (US); Jeff Shimizu, Cortlandt Manor, NY (US); Johan Frederik Dijksman, Weert (NL); Anke Pierik, Eindhoven (NL); Judith Margreet Rensen, Eindhoven (NL); Adam Schleicher, Briarcliff Manor, NY (US); Frits Tobi De Jongh, Beek En Donk (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/521,015

(22) PCT Filed: Dec. 26, 2007
(86) PCT No.: PCT/IB2007/055311

§ 371 Date: Jun. 24, 2009

Related U.S. Application Data
(60) Provisional application No. 60/882,009, filed on Dec. 27, 2006.

(51) Int. Cl. G01R 27/26

(52) U.S. Cl. 324/663

(57) ABSTRACT

A fluid sensor for use within the gastro-intestinal tract of a human being is disclosed. The sensor includes a sensing coil which is immersible in the sample fluid of the gastro-intestinal tract; a signal generator in electrical with the sensing coil for applying an electrical current pulse to the sensing coil; a signal receiver in communication with the sensing coil for measuring an electrical reflection relative to said electrical current pulse; and a data processor for receiving the electrical reflection and for calculating data representative of at least one property, such as pH of the sample fluid based on the electrical reflection. The fluid sensor can also include a reference coil for calibrating the sensing coil. The sensor coil and reference coil can be encapsulated in a swallowable pill shell. The sensor coil can also function as an antenna for transmitting and receiving signals to/form a remote location.

### TECHNICAL FIELD

The present disclosure relates to measuring fluid properties inductively and, more particularly, to a method and apparatus for measuring pH in the gastro-intestinal track (GI) of a human being or other fluid system.

### BACKGROUND OF THE INVENTION

A coil can be modeled based on frequency-dependent impedance having a capacitive and inductive component, e.g., as shown with reference to FIG. 2. The inductance L of the coil 12 can be calculated from:

$$L = {μ}_{0} {μ}_{r} \frac{{N}^{2} A}{l}$$

where,

μ₀ is the permeability of free space (4π'10⁻⁷ Henries per meter),

μᵣ is the relative permeability of the core 14 (dimensionless),

N is the number of turns of the coil 12,

A is the cross sectional area of the coil 12 in square meters,

I is the length of the coil 12 in meters,

Of note, the inductance L of a coil 12 is proportional to the relative permeability of the core 14.

In practice, every coil also has DC resistance R and combined, distributed capacitances C. The capacitance C of an electrical component is dependent on its physical configuration and is generally proportional to the dielectric constant of the core 14 of the coil 12 that separate adjacent windings of the coil 12. The complex impendence Z_{LRC} of the coil 12 is a function of frequency and, as a first order approximation, can be given by:

$$\frac{1}{{Z}_{LRC}} = \frac{1}{R + j ω L} + j ω C$$

where, ω=2πf, f is the frequency of an applied signal.

The impedance of the coil 12 can reach a maximum value at a certain frequency (resonance frequency). If such a coil is immersed in a sample fluid 22 that has a frequency-dependent dielectric constant and/or magnetic permeability, multiple resonance frequencies may be observed. In such cases, L and C become a function of frequency, given by

$$\frac{1}{{Z}_{LRC} ( ω )} = \frac{1}{R + j ω {μ}_{0} {μ}_{r} ( ω ) \frac{{N}^{2} A}{l}} + j ω {ɛ}_{0} {ɛ}_{r} ( ω ) G$$

where:
ε₀ permittivity of free space, 8.845×10⁻¹² [F/m]
δᵣ(ω) is the frequency dependent relative permittivity of the sample fluid (dimensionless)
G is a frequency independent geometric expression describing the equivalent capacitance of the inductor [m]
μᵣ(ω) is the frequency dependent relative permeability of the sample fluid (dimensionless)

Therefore, the frequency-dependent impedance Z_{LRC}(ω) of a coil can further reveal the frequency-dependent variation of both dielectric constant and magnetic permeability, which depends on type and concentration of ions in a sample fluid.

Gastrointestinal fluid contains many substances whose concentration is important biomedical indicators for diagnosis of digestive activities and anatomical locations. These substances include ion concentration, enzymes, glucoses etc. An important quantity of measurement in both chemical and biological systems is pH. pH is an abbreviation for “pondus hydrogenii” and was proposed by the Danish scientist S.P.L. Sørensen in 1909 in order to express very small concentrations of hydrogen ions (H+). The precise formula for calculating pH is:

pH=−log₁₀aH

where aH denotes the activity of H⁺ ions and is unitless. One technique for measuring pH is to employ two glass electrodes: an indicator electrode and a reference electrode. In a typical modern pH probe, the glass and reference electrodes are combined into one body. The pH meter is best thought of as a tube within a tube. Inside the inner tube is a cathode terminus of the reference probe. The anodic indicator electrode wraps itself around the outside of the inner tube and ends with the same sort of reference probe as was on the inside of the inner tube. Both the inner tube and the outer tube contain a reference solution, but only the outer tube has contact with the solution on the outside of the pH probe by way of a porous plug that serves as a salt bridge.

As assembled, the device is essentially a galvanic cell. The reference end is essentially the inner tube of the pH meter, which cannot lose ions to the surrounding environment. The outer tube contains the medium, which is allowed to mix with the outside environment. A response is caused by an exchange at both surfaces of the swollen membrane between the ions of the glass and the H+ of the solution—an ion exchange that is controlled by the concentration of H+ in both solutions.

Among many parameters of clinic significance, pH value of the gastro-intestinal (GI) tract is important because it can be used to diagnose disease and/or to locate a position inside the GI tract. Efforts at miniaturizing pH-sensing technology based on glass electrodes have had limited success. To date, the smallest pH-sensing device known in the art is the Heidelberg pH capsule, which measures 7.1 mm×15.4 mm. This device measures pH values in vivo and reports data telemetrically.

A further pH-sensing technology of note is based on an ion sensitive field effect transistor (ISFET). In an ISFET, an H+ sensitive buffer coating is applied to a gate electrode. The voltage drop between the drain and source electrodes becomes a function of H+concentration to that which the gate is exposed. An ISFET-based pH-sensor can be built into a relatively small volume (on the order of mm³). Although an ISFET pH-sensor can be made very small, its biocompatibility has been a concern.

A problem with both glass pH sensors and pH sensors based on an ISFET is the phenomenon of memory effect. In transitory environments, travel from a first location to a second location (particularly a second location devoid of flowing fluid), a pH sensor based on either of the prior art technologies may still read the pH value of the first location. Since both pH-sensors rely on ion diffusion, they will show a memory effect if trapped ions do not have a chance to diffuse away. As a result, glass-electrode pH meters require frequent “conditioning”.

What would be desirable is a pH-sensor which can fit into the volume of an electronic pill or other comparable unit, is biocompatible, and is free of memory effects. These and other advantages are achieved by the method and apparatus described herein. Indeed, based on the advantageous designs and design principles disclosed herein, sensors which can sense other properties of fluid without material exchange can also be designed, built and implemented.

### SUMMARY

The present disclosure relates to a system and method for measuring fluid properties, particularly pH, within the gastrointestinal (GI) tract of a human or other fluid system, e.g., a tap water system. In an exemplary embodiment, a pH sensing method involves providing a sensing coil having an ion-selective polymer coating, the sensing coil being immersible in the fluid of a gastrointestinal tract (or other fluid system); providing a signal generator in communication with the sensing coil for applying an electrical current pulse to the sensing coil; providing a signal receiver in communication with the sensing coil for measuring an electrical reflection relative to said electrical current pulse; and providing a data processor for receiving the electrical reflection and for calculating data representative of the pH of a sample fluid based on the electrical reflection. Of note, a pH sensor and associated sensing coil according to exemplary embodiments of the present disclosure do not require material exchange with the sample fluid and exhibit no memory effect.

In another exemplary embodiment of the present disclosure, the disclosed pH sensor also includes a reference coil having an air core for receiving signals from a background electrical environment shared with the sensing coil for calibrating the sensing coil. Predetermined values for reflectance stored in or accessible by the data processor can be compared with measured reflectance values to calculate a pH value. In preferred anatomical implementations of the pH sensing technology described herein, the sensor coil and reference coil are encapsulated in a swallowable pill shell.

In another embodiment, the pH sensor can include a pill shell equipped with a microprocessor, transceiver, and a coil shaped antenna. The coil shaped antenna functions as both a pH sensing coil and a means of transmitting and receiving signals to/from the transceiver to/from a remote location. The coil shaped antenna is coated with a pH sensitive polymer. The sensing coil, transceiver, and microprocessor function together as a frequency responsive analyzer.

Additional features, functions and benefits of the disclosed pH sensing technology will be apparent from the description which follows, particularly when read in conjunction with the appended figures.

### BRIEF DESCRIPTION OF THE DRAWINGS

For a more complete understanding of the present disclosure, reference is made to the following detailed description of exemplary embodiments considered in conjunction with the accompanying drawings, in which:

FIG. 1 is a block diagram of a fluid sensor having a sensing coil in accordance with an exemplary embodiment of the present disclosure;

FIG. 2 is an electrical schematic diagram which models the electrical behaviour of the sensing coil of FIG. 1;

FIG. 3 is a block diagram of a pH sensor having a sensing coil and a reference coil in accordance with another embodiment of the present disclosure;

FIG. 4 is a schematic view of an exemplary electronic pill incorporating the pH sensor of FIG. 3, constructed in accordance with a third embodiment of the present disclosure;

FIG. 5 is a block diagram of test setup for measuring the frequency response of a pH sensing coil according to the present invention;

FIG. 6 is plot of relative reflection versus frequency for reflection of a signal from an exemplary sensing coil according to the present disclosure, wherein the core of the coil is filled with tap water of different pH values;

FIG. 7 is an expanded view of FIG. 6 in the frequency band of 100 MHz to 180 MHz;

FIG. 8 is an expanded view of FIG. 6 in the frequency band of 420 MHz to 520 MHz; and

FIG. 9 is plot of relative reflection versus frequency over a frequency range of 250 MHz to 300 MHz for reflection of a signal from an exemplary sensing coil according to the present disclosure, and wherein the core of the coil is filled with salt water of different pH values.

### DETAILED DESCRIPTION OF EXEMPLARY EMBODIMENT(S)

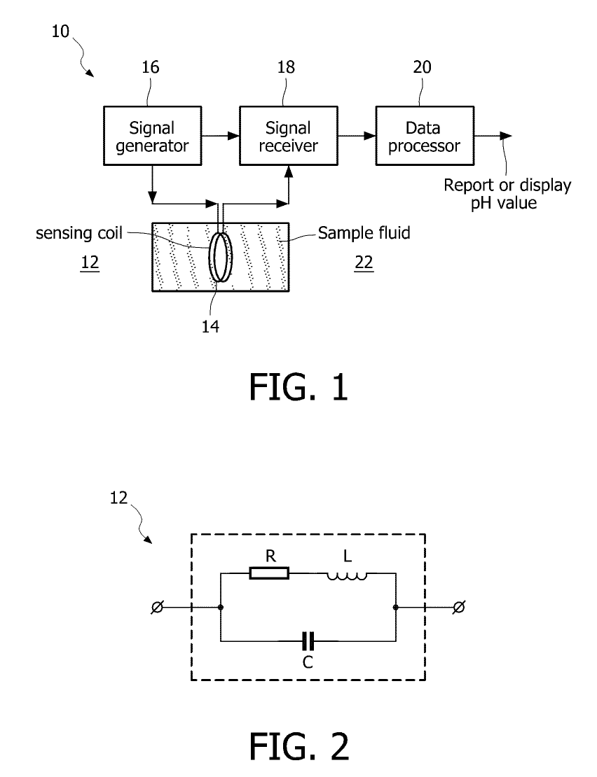

With reference to FIG. 1, a block diagram of an exemplary fluid sensor 10 in accordance with the present invention is depicted. The fluid sensor 10 includes a sensing coil 12 with air core 14. The fluid sensor is in communication with a signal generator 16, a signal receiver 18 and a data processor 20. When a property of a medium is to be measured, the air core 14 is filled with a sample fluid 22. The wires of the sensing coil 12 may be coated with a non-conductive material for making the sensing coil 12 less reactive to the sample fluid 22, thereby enhancing the reliability and repeatability of sensor response. The coating material for the coil 12 is preferably, but not limited to, materials that are immune to interference of salt ions that may be present in the sample fluid 22. Such coating materials include an ion-selective polymer such as poly(vinylbenzylchloride-co-2,4,5-trichlorophenyl acrylate) (“VBC-TCPA”) or an H-ion permeable polymer, such as NAFION perfluorosulfonic/PTFE copolymer available from DuPont. The sensing coil 12 does not have to be circular (as schematically depicted in FIG. 1), but can take other preferred shapes. In addition, the sensing coil 12 need not be immersed in sample fluid 22 as long as the core 14 of the coil 12 is substantially filled with the sample fluid 22, for example, when a fluid-filled tube is held inside the coil core.

In operation, signal generator 16 sends an AC pulse of certain bandwidth to the sensing coil 12. The signal receiver 18 receives and records the response of the sensing coil 12 to the AC pulse. The characteristic response to the applied AC signal of the sensing coil 12, whose core 14 is filled with sample fluid 22, is used to derive the pH value of a sample fluid 22. The response of the coil-medium combination is analyzed by the data processor 20. The signal generator 16, signal receiver 18, and data processor 20 can function as a frequency response analyser. Preferably the frequency response is measured in the range of 350-450 MHz centered around 433 MHz. Since the response of the sensing coil 12 depends on its construction and configuration and usually does not change, then the property-dependent response of the coil 12 can be stored in a memory (not shown) associated with the data processor 20 to simplify data processing. During measurement, the measured response of the coil 12 may be advantageously compared with stored property-dependent response data, e.g., in the form of a look-up table, to determine the property value of the sample fluid 22. As noted above, a coil can be modelled based on capacitive and inductive components, as schematically depicted in FIG. 2.

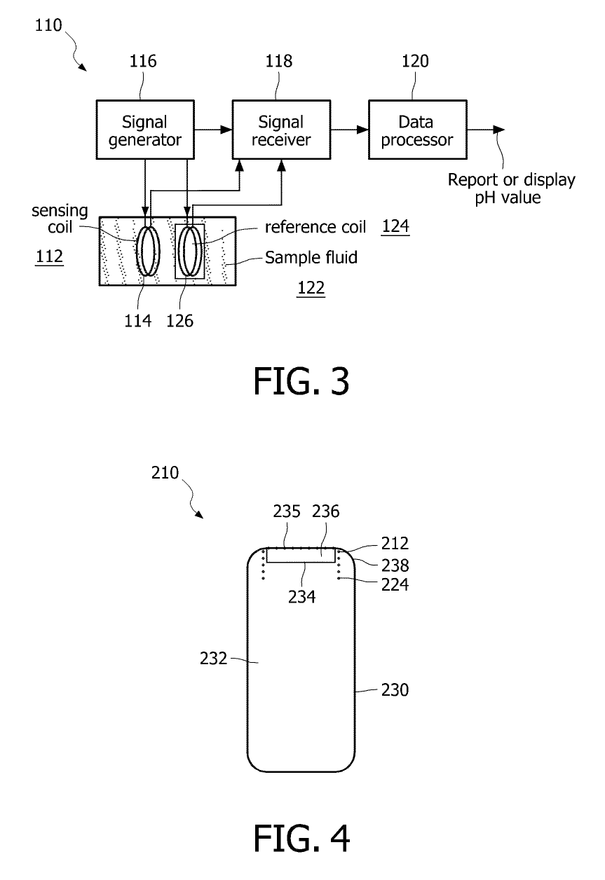

With reference to FIG. 3, a block diagram of an exemplary pH sensor having a sensing coil and a reference coil in accordance with a second embodiment of the present disclosure is depicted. Elements illustrated in FIG. 3 which correspond to the elements described above in connection with the fluid sensor 10 of FIG. 1, have been identified by corresponding reference numbers increased by one hundred.

In the exemplary embodiment of FIG. 3, the pH sensor 110 includes a sensing coil 112 with air core 114 and a reference coil 124 with air core 126 in communication with a signal generator 116, a signal receiver 118 and a data processor 120. In the embodiment of FIG. 3, a pair of identical coils 112,124 are used to build the sensor 110. The sensing coil 112 is used to sense the sample fluid 122. The reference coil 124 is used as reference to eliminate environmental electromagnetic interference and is not exposed to the sample fluid 122. The reference coil 124 has a fixed core made of either air, liquid, or other material.

In operation, the signal generator 116 sends an AC pulse of a predetermined bandwidth to both the sensing coil 112 and the reference coil 124. The signal receiver 118 receives and records the response of both the sensing coil 112 and the reference coil 124 to the AC pulse. The electrical response of the reference coil 124 is used by the data processor 120 to calibrate the background electrical environment of the sensing coil 112, which is used to eliminate (factor out) environmental electromagnetic interference from the response of the sensing coil 112. The calibrated response of the sensing coil 112 is analyzed by the data processor 120 to derive a pH value of the intervening sample fluid 122.

Since the response of the coils 112, 124 depends on its construction and configuration and usually does not change, then the pH-dependent responses of the coils 112, 124 can be characterized in advance by storing them in a memory (not shown) associated with the data processor 120 to simplify data processing. During pH measurement, the measured response of the coil 112 is compared with the stored pH-dependent response data, e.g., in the form of a look-up table, to determine the pH value of the sample fluid 122.

With reference to FIG. 4, a block diagram of a further exemplary pH sensor 210 having a sensing coil 212 and a reference coil 224 integrated into an electronic pill shell 230 in accordance with a third embodiment of the present disclosure is depicted. Elements illustrated in FIG. 4 which correspond to the elements described above in connection with the pH sensor 110 of FIG. 3 have been identified by corresponding reference numbers increased by one hundred. Unless otherwise indicated, both the pH sensor 110 and the pH sensor 210 have the same construction and operation. The pill shell 230 has a pill shell body 232 having a rectangular indentation 234 which is enclosed on one side by a membrane 235 so as to form a void 236 within the pill shell 232 at one end 238 of the pill shell body 232. The sensing coil 212 and the reference coil 224 are integrated into an electronic pill shell, as shown, with the sensing coil 212 employing the void 236 as its core and the reference coil 224 contained within the pill shell body 232 unexposed to any liquids. Since the membrane 234 is semi-permeable, solid particles do not enter the void 236, but a sample liquid medium can. The disclosed embodiment of pH sensor 210 is advantageously small enough to be swallowed, thereby entering the GI tract of a patient. There is no exposure of electrodes to the GI environment according to the design/operation of pH sensor 210, thereby eliminating any biocompatibility or toxicity issues. There is also no physical penetration of the pill shell 230 with wires or leads to the coils 212, 224 located inside.

In yet another embodiment of the present disclosure, a pill shell similar to the pill shell 230 may be equipped with a microprocessor, transceiver, and a coil shaped antenna. The coil shaped antenna functions as both a pH sensing coil and a means of transmitting and receiving signals to/from the transceiver to/from a remote location. According to exemplary embodiments of the present disclosure, the coil shaped antenna is advantageously coated with a pH sensitive polymer, e.g., one of the polymers disclosed with reference to the embodiments of FIGS. 1, 3 and 4. The microprocessor together with the transceiver and the antenna/coil function as a frequency response analyser.

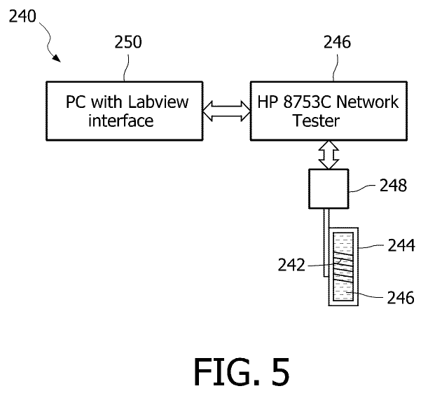

With reference to FIG. 5, an exemplary test setup 240 for measuring frequency response of a pH sensing coil according to the present disclosure is depicted. The test setup 240 includes a copper coil 242 with air core surrounding a round plastic cuvette 244 which contains sample fluid 246 under test. The copper coil 242 is generally fabricated from an appropriate wire gauge, e.g., 30 gauge wire, and is subject to a desired coiling, e.g., 30 turns, to form an inductor having an inductance of about 0.01 mH with an air core at low frequency. In an exemplary embodiment, the round plastic cuvette 244 has an outer diameter of about 8 mm and an inner diameter of about 6 mm. A signal generator and signal transceiver are simulated using a model HP 8753C Network Tester 246 manufactured by Hewlett-Packard. The copper coil 242 is electrically coupled to the Network Tester 246 via a BNC connector 248. The data processor is simulated by a personal computer (PC) equipped with a Labview data acquisition interface 250 for displaying data.

A variety of fluids may be sampled using the disclosed test setup. For example, tests have been performed with tap water modified to have several values of pH, salt water modified to have several values of pH, simulated gastric fluid (SGF), and simulated intestinal fluid (SIF). The tap water pH was adjusted to values of 7.3, 6.1, 5.1, 4.1, 3.2, 2.1 and 1.0 by mixing with HCl and calibrated with a CHEKMITE pH-15 glass electrode pH-meter manufactured by Corning. The salt water solutions included 0.2% salt adjusted to pH's of 7.0, 5.1, 4.0, 3.1, 2.0 and 1.1. The simulated gastric fluid (SGF) without protein was obtained from Ricca Chemical Part#7108-32 with 0.2% w/v NaCl in 0.7% v/v HCl (pH 1.1). The simulated intestinal fluid (SIF) was USPXXII obtained from Ricca Chemical Part#7109.75-16 mixed with 0.68% monobasic potassium phosphate, and sodium hydroxide with the pH of the final solution set to about 7.4.

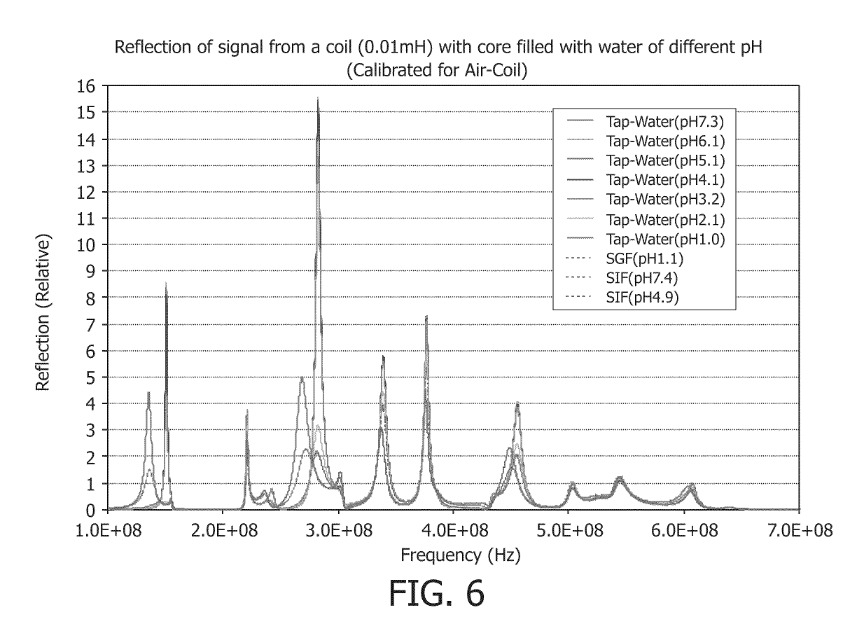

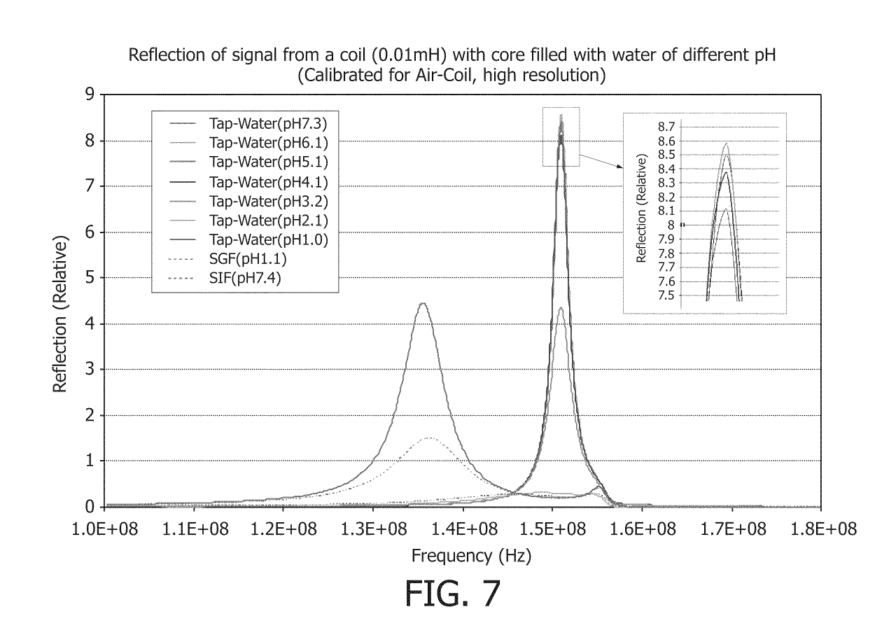

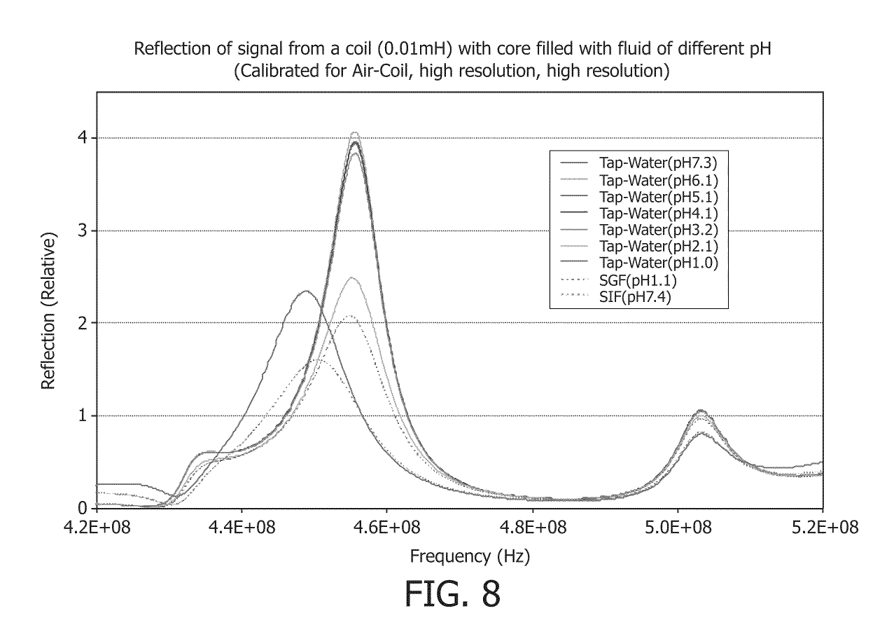

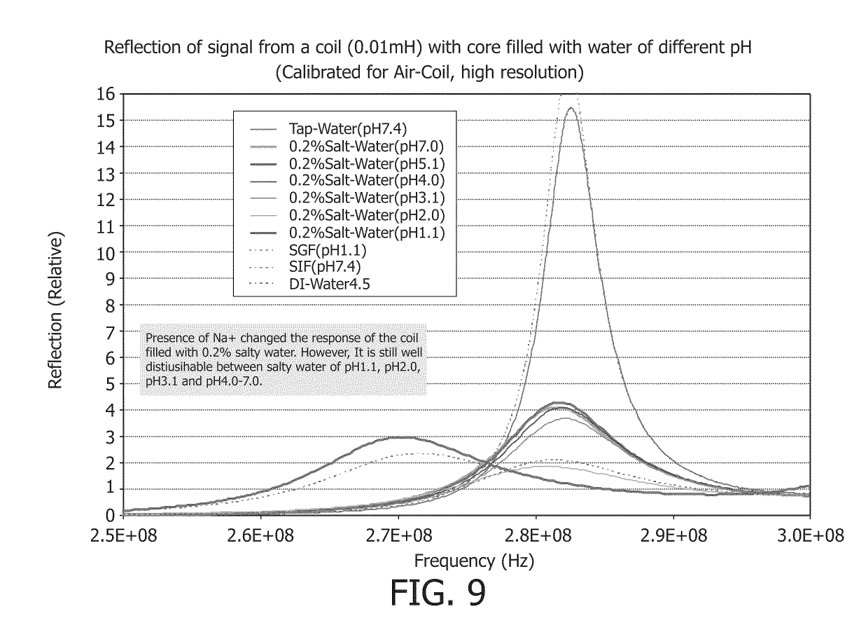

FIGS. 6-9 show plots of relative reflection versus frequency from experimental data using the disclosed test setup to measure pH value of the various sample fluids discussed above. FIG. 6 shows the overall relative reflection vs. frequency for tap water solutions of various pH values, SGF at pH 1.1, and SIF at pH's 7.4 and 4.9. FIG. 7 is an expanded view of FIG. 6 in the frequency band of 100 MHz to 180 MHz. FIG. 8 is an expanded view of FIG. 6 in the frequency band of 420 MHz to 520 MHz. FIG. 9 shows the relative reflection vs. frequency over a frequency range of 250 MHz to 300 MHz for salt water solutions of various pH values, SGF at pH 1.1, and SIF at pH 7.4, deionized water at pH 4.5, and tap water at pH 7.4.

In the results reflected in FIG. 9, the presence of Na⁺ ion in the salt water changes the response of the coil, but salt water pH's of 1.1, 2.0, 3.1 and 4.0-7.0 are still distinguishable from each other using the disclosed apparatus/method. The conductivity of the sample fluid increases with decreasing pH. It is also noted from the plots of FIGS. 6-9 that the reflective response of the coils can be attributed to a greater degree to changes in dielectric constant (or conductivity), rather than changes in magnetic permeability.

The methods and apparatus of the present disclosure offer several advantages over prior art pH sensing devices. For example, the disclosed methods and apparatus provide a fast and responsive pH sensing mechanism which can be manufactured in a very small form factor. Indeed, the geometry and other physical attributes of the disclosed pH sensing devices may be configured and dimensioned for human ingestion, thereby providing pH sensing to a variety of GI tract locations. The pH sensor of the present disclosure is also free of material (ion) exchange, is generally free of memory effects, and can be manufactured and utilized in a cost effective fashion.

The methods and apparatus of the present disclosure are subject to numerous applications. The disclosed pH sensing method and apparatus may find applications to determine approximate pH values of sample fluids with known basic compositions, for example, in measuring the in vivo pH value of gastrointestinal fluid. Further, the present invention may be used as an in-line pH sensor to monitor the pH value of fluid in pipes or for monitoring the pH value of tap water in a residence. Still further, the methods and apparatus of the present invention may be integrated with a radio frequency identification device (RFID) to monitor the pH value of a bottled beverage or other product/system.

It will be understood that the embodiments described herein are merely exemplary and that a person skilled in the art may make many variations and modifications without departing from the spirit and scope of the invention. All such variations and modifications are intended to be included within the scope of the invention.

1. A fluid sensor system, comprising:
a sensing coil, said sensing coil having a core and an isolation coating, wherein said sensing coil core is configured for being in substantially filled with a sample fluid;
a signal generator in communication with said sensing coil for applying an alternating current pulse of a predetermined bandwidth to said sensing coil;
a signal receiver in communication with said sensing coil for measuring an electrical reflection produced by said sensing coil relative to said alternating current pulse, wherein said electrical reflection is based upon a property-dependent response of a combination of (i) said sensing coil and (ii) the sample fluid that substantially fills the sensing coil core; and
a data processor for receiving said electrical reflection and for calculating data representative of at least one property of the sample fluid based on said measured electrical reflection.

2. The sensor system of claim 1, wherein said sensing coil is sized and shaped to fit within a pill shell that can travel through the gastro-intestinal tract of a human being.

3. The sensor system of claim 2, further comprising a pill shell having a body and a void within the pill shell at an end of the body, wherein said sensing coil is integrated within said pill shell and wherein said sensing coil employs the void as the core of the sensing coil.

4. The sensor system of claim 2, wherein said isolation coating is an ion-selective polymer coating that is substantially immune to interference of unselected ions present in the sample fluid.

5. The sensor system of claim 4, wherein said ion-selective polymer coating is fabricated, at least in part, from VBC-TCPA.

6. The sensor system of claim 4, wherein said ion-selective polymer coating is an H-ion permeable polymer.

7. The sensor system of claim 4, wherein said ion-selective polymer coating is fabricated, at least in part, from a perfluorosulfonic/PTFE copolymer.

8. (canceled)

9. The sensor system of claim 1, wherein said data processor compares stored reflectance values with measured reflectance values to determine a value of the at least one property of the sample fluid.

10. The sensor system of claim 1, further comprising a reference coil identical to said sensing coil and having an air core, said reference coil for receiving signals from a background electrical environment shared with said sensing coil for calibrating said sensing coil.

11. (canceled)

12. The sensor system of claim 10, wherein said data processor compares stored reflectance values with measured reflectance values to determine a value of the at least one property of the sample fluid

13. The sensor system of claim 3, wherein said pill shell further comprises a semi-permeable membrane for allowing the sample fluid to enter the void corresponding to the core of the sensing coil and for blocking solid particles from entering the void.

14. The sensor of claim 10, wherein said reference coil is unexposed to the sample fluid.

15. A sensor according to claim 1, wherein the at least one property of the sample fluid comprises pH.

16. A pH sensor, comprising:
a sensing coil, said sensing coil having a core and an ion-selective polymer coating, wherein said sensing coil core is configured for being substantially filled with a sample fluid;
a transceiver in electrical communication with said sensing coil, wherein said transceiver is configured for applying an alternating current pulse of a predetermined bandwidth to said sensing coil, said transceiver further configured for measuring an electrical reflection produced by said sensing coil relative to said alternating current pulse, wherein said electrical reflection is based upon a property-dependent response of a combination of (i) said sensing coil and (ii) the sample fluid that substantially fills the sensing coil core; and
a microprocessor in electrical communication with said transceiver, wherein said microprocessor is configured for calculating data representative of pH of the sample fluid based upon said measured electrical reflection, further
wherein said sensing coil, said transceiver, and said microprocessor function together as a frequency responsive analyzer for determining pH of the sample fluid.

17. A pH sensor of claim 16, further comprising a reference coil.

18. A pH sensor of claim 17, wherein the reference coil identical to the sensing coil and having an air core, the reference coil for receiving signals from a background electrical environment shared with the sensing coil for calibrating the sensing coil.

19. (canceled)

20. A pH sensor, comprising:
a sensing coil, said sensing coil having a core and an ion-selective polymer coating, wherein said sensing coil core is configured for being in substantially filled with a sample fluid, said sensing coil further configured for functioning as an antenna for transmitting pH measurements of the sample fluid to a remote location;
a transceiver in electrical communication with said sensing coil, wherein said transceiver is configured for applying an alternating current pulse of a predetermined bandwidth to said sensing coil, said transceiver further configured for measuring an electrical reflection produced by said sensing coil relative to said alternating current pulse, wherein said electrical reflection is based upon a property-dependent response of a combination of (i) said sensing coil and (ii) the sample fluid that substantially fills the sensing coil core; and
a microprocessor in electrical communication with said transceiver, wherein said microprocessor is configured for calculating data representative of pH of the sample fluid based
upon said measured electrical reflection, further wherein said sensing coil, said transceiver, and said microprocessor function together as a frequency responsive analyzer.

21. A method of measuring pH of a sample fluid using an electronic pill comprising a sensing coil having a core and an ion-selective polymer coating, wherein the core is configured for being substantially filed with the sample fluid, said method comprising the steps of:
substantially filling the core of said sensing coil with the sample fluid;
applying an electrical current pulse of a predetermined bandwidth to said sensing coil;
measuring an electrical reflection produced by said sensing coil relative to said electrical current pulse, wherein said electrical reflection is based upon a property-dependent response of a combination of (i) said sensing coil and (ii) the sample fluid that substantially fills the sensing coil core; and
calculating data representative of the pH of the sample fluid based on said measured electrical reflection.

22. The method of claim 21, wherein said step of calculating further comprising the step of comparing stored reflectance values with measured reflectance values to determine the pH value.

23. The method of claim 21, wherein the sample fluid is fluid associated with a gastrointestinal tract of a human being.
